(19) United States
(12) Patent Application Publication
(10) Pub. No.: US 2021/0289658 A1
(43) Pub. Date: Sep. 16, 2021

(54) IMPROVED HEAT SINK AND HEAT DISSIPATION STRUCTURE

(71) Applicant: TTI (MACAO COMMERCIAL OFFSHORE) LIMITED, Macao (CN)

(72) Inventor: Hei Man Raymond LEE, Kwai Chung (HK)

(21) Appl. No.: 16/330,527

(22) PCT Filed: Sep. 21, 2016
(86) PCT No.: PCT/CN2016/099638

§ 371 Date: Mar. 5, 2019

(51) Int. Cl. H05K 7/20; B25F 5/00

(52) U.S. Cl. CPC H05K 7/20154; B25F 5/008

(57) ABSTRACT

A printed circuit board assembly (PCBA) has a heat source, a heat sink, and an exit vent. The heat source generates heat, typically excessive heat and the heat sink conducts heat from the heat source and heats up the surrounding air to form heated air. The heated air then passes through the exit vent which is positioned adjacent to the heat sink. In addition, a heat dissipation structure contains a fan to move air, a heat source distal from the fan, an exit vent proximal to the fan, and an airflow path running from the heat source to the fan to the exit vent. The heat source heats the air to form heated air. When the fan is activated, the fan draws air through the airflow path from the heat source and out of the exit vent.

### FIELD OF THE INVENTION

The present invention is related to heat sinks and heat dissipation structures.

### BACKGROUND

Excess heat is a problem in may items such as motors, batteries, electronics, tools, computers, chargers, etc. Many different designs and strategies exist to actively and passively dissipate unwanted heat. While some of these methods rely upon various heat sinks, and even heat sinks with air being blown directly thereupon by a fan, such a fan requires additional energy to operate d thus may cause other issues.

Certain passive heat dissipation structures are known and may use ambient air to draw away heat. However, such passive structures are less efficient than active structures.

Accordingly, the inventors believe that a more effective strategy is needed to improve heat dissipation. Thus, there remains a need for improved heat sinks and heat dissipation structures.

### SUMMARY OF THE INVENTION

An embodiment of the present invention relates to a printed circuit board assembly (PCBA) having a heat source, a heat sink, and an exit vent. The heat source generates heat, typically excessive heat and the heat sink conducts heat from the heat source and heats up the surrounding air to form heated air. The heated air then passes through the exit vent which is positioned adjacent to the heat sink.

Without intending to be limited by theory, it is believed that such a passive venting system is extremely efficient and permits the flow of the heated air itself to create a low pressure zone above the heat sink which then draws surrounding air to the heat sink. This in turn further cools the heat sink. Furthermore, such an embodiment may be virtually silent, as no moving mechanical parts are needed.

An embodiment of the present invention also relates to a heat dissipation structure containing a fan to move air, a heat source distal from the fan, an exit vent proximal to the fan, and an airflow path running from the heat source to the fan to the exit vent. The heat source heats the air to form heated air. When the fan is activated, the fan draws air through the airflow path from the heat source and out of the exit vent.

Without intending to be limited by theory, it is believed that such a heat dissipation structure may he extremely efficient while also requiring little energy for such a fan, Thus, it is believed that the embodiment is actually more efficient than a fan which blows air directly upon a heat source, as it may draw comparatively more air past the heat source.

### BRIEF DESCRIPTION OF THE DRAWINGS

FIG. 1 shows a cut-away side view of embodiment of the heat sink of the present invention;

FIG. 2 shows a partial, top perspective view of an embodiment of a PCBA of the present invention;

FIG. 3 shows a cut-away schematic view of an embodiment of the heat dissipation structure of the present invention; and

FIG. 4 shows a cut-away schematic view of an embodiment of the heat dissipation structure of the present invention.

The figures herein are for illustrative purposes only and are not necessarily drawn to scale.

### DESCRIPTION OF THE PREFERRED EMBODIMENTS

Unless otherwise specifically provided, all tests herein are conducted at standard conditions which include a room and testing temperature of 25° C., and all measurements are made in metric units. Furthermore, all percentages, ratios, etc. herein are by weight, unless specifically indicated otherwise.

An embodiment of the present invention relates to a printed circuit board assembly (PCBA) having a heat source, a heat sink, and an exit vent. The heat source generates heat, typically excessive heat which could be detrimental to the long-term stability of the PCBA, or whatever the PCBA is installed within, and/or the excessive heat could cause other problems. The heat source is connected to the heat sink, and typically the heat source is physically connected to; or touching the heat sink. The heat sink conducts heat from the heat source and heats up the surrounding air to form heated air. The heated air then passes through the exit vent which is adjacent to, and typically directly above, the heat sink. Without intending to be limited by theory, it is believed that such a passive venting system is extremely efficient and permits the flow of the heated air itself to create a low pressure zone above the heat sink which then draws surrounding air to the heat sink. This in turn further cools the heat sink. Furthermore, such an embodiment may be virtually silent, as no moving mechanical parts are needed.

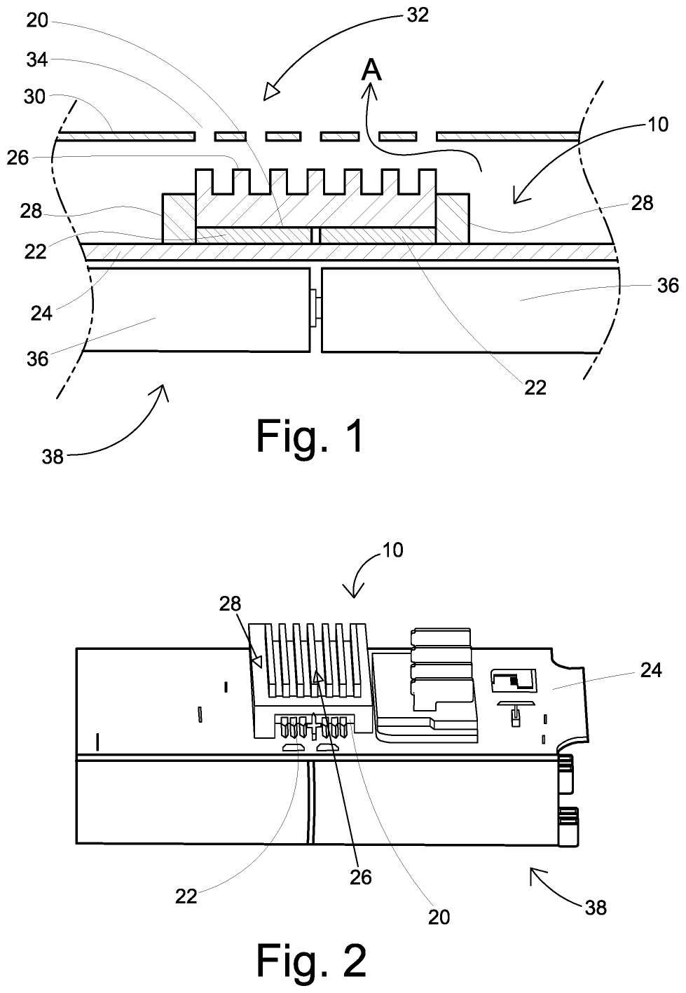

Turning to FIG. 1, which shows a cut-away side view of an embodiment of the present invention, we see a PCBA, 10, containing a heat source, 20, which generates heat that needs to be dissipated. In this embodiment the heat source, 20, is a set of field-effect transistors (FETs), 22, typically from about 1 FET to about 32 FETs; or from about 2 FETs to about 16 FETs; or from about 3 FETs to about 8 FETs; or about 4 FETs grouped together. Without intending to be limited by theory, it is believed that FETs, 22, grouped together can produce an excessive amount of heat which may need to be dissipated and/or removed. However, the heat source need not be a FET, but may be, for example, a battery, a battery case, a battery pack, a motor, a capacitor, an electrical circuit, etc. In an embodiment of the present invention the heat source is selected from the group consisting of a battery, a motor, a transistor, a gear box, and a combination thereof; or a battery, a transistor and a combination thereof; or a battery; or a transistor.

The heat source, 20, in FIG. 1 is connected to a substrate, 24, Which is the mechanical support for the PCBA. In an embodiment herein the substrate is formed from, or contains, (a.k.a. “FR4”), a glass-reinforced laminate sheet formed from a woven fiberglass cloth and an epoxy resin. Such a substrate is standard and well-known in the electronics and PBCA art for holding electronic components and for.

In FIG. 1, the heat source, 20, directly contacts the heat sink, 26, which in turn conducts heat away from the heat source, 20. The heat sink is typically of a shape which intends tin increase the surface area thereof, so as to better dissipate the heat to the surrounding air, Accordingly, the heat sink may have a set of furrows and a set of raised ridges so as to increase the surface area over, for example, a plain rectangular block. Designs to increase the surface area of the heat sink are known to those in the relevant art, and any such design may be useful in the present invention.

In the embodiment of FIG. 1, the heat sink, 26, is affixed to the substrate, 24, and is held in place by the heat sink holder, 28. In this embodiment, the heat sink holder, 28, is affixed to the heat source, 20, hi an embodiment herein, the heat sink holder is affixed to the substrate, In an embodiment herein, the heat sink holder is affixed to the heat source; or the heat sink holder is permanently affixed to the heat source; or the heat sink is removably-affixed to the heat source, in an embodiment herein, the heat sink holder is physically connected to the heat source.

The heat sink may be formed of any suitable thermally-conductive material, such as a metal, a plastic, and a combination thereof; or a metal. In addition, the material for the heat sink should also be relatively sturdy and preferably cheap. The metal may be, for example, copper, iron, aluminium, tin, brass, and a combination thereof; or copper aluminium, brass and a combination thereof; or copper.

The heat sink holder is typically formed of a material which is less thermally-conductive than the heat sink, is relatively resistant to heat (i.e., will not melt or burn at the relevant temperatures), is easy to form into the desired shape and is relatively cheap to produce. Accordingly, in an embodiment herein, the heat sink holder is formed of a plastic; or a high-impact plastic; or a thermally-resistant plastic.

FIG. 1 also shows a housing, 30, distal from the heat source, 20, The housing, 30, may be, for example, a battery housing, a generator housing, a power tool housing, a battery pack housing, a charging station housing, etc. as desired. The housing, 30, contains an exit vent, 32, formed from a plurality of parallel slits, 34, in the housing, 30. In an embodiment herein, the parallel slits form a pattern, such as a grid pattern, a diagonal pattern, etc.

In FIG. 1, this housing, 30, also aligns the substrate, 24, opposite to the exit vent, 32, with the heat source, 20, the heat sink, 26, and the heat sink holder, 28, therebetween. In order to maximize dissipation of the excessive heat and heated air into the ambient air outside of the housing, 30, the exit vent, 32, is adjacent to; or directly above, the heat sink, 26, although other positions adjacent to the heat sink, 26, are also within the scope of the present invention.

The heat sink, 26, conducts heat away from the heat source, 20, and heats up the air surrounding the heat sink to form heated air. The heated air then rises and flows out of the exit vent, 32. Without intending to be limited by theory, it is believed that this rising heated air creates a low pressure zone above the heat sink, 26, which then draws additional air past the heat sink, 26, and out of the vent, 32, as shown by arrow A. Such a design therefore increases the efficiency and cooling of the heat sink by drawing not only air directly touching the heat sink but additional air via the Bernoulli principle.

In FIG. 1, it can be seen that the PCBA, 10, is connected to a series of batteries, 36, which are part of a battery pack, 38. The FETs, 22, may generate excessive heat during, for example, the charging and/or discharge of the battery pack.

In FIG. 2 shows a partial, top perspective view of an embodiment of a PCBA, 10, of the present invention, which is part of a battery pack, 38. The FET, 22, and the heat sink holder, 28, are affixed to the substrate, 24. The heat sink holder, 28, is affixed to the heat sink, 26, and prevents it from breaking contact with the heat source, 20.

Another embodiment of the present invention relates to a heat dissipation structure having a fan, a heat source distal to the fan, an exit vent proximal to the fan, and an airflow path. The airflow path runs from the heat source to the fan to the exit vent. The heat source heats the air to form heated air. When the fan is activated, the fan draws air through the airflow path from the heat source and out of the exit vent.

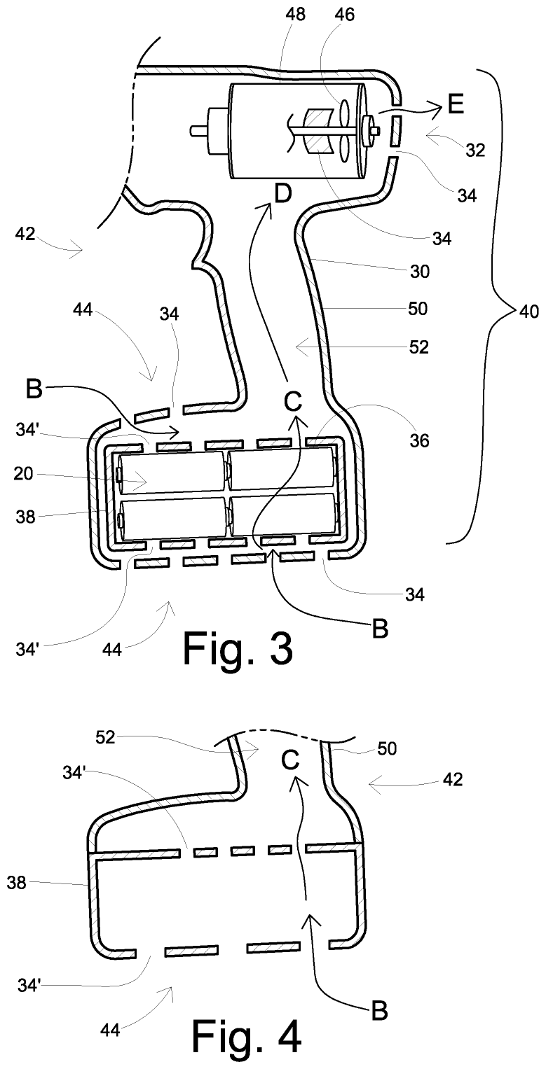

FIG. 3, shows a cut-away schematic view of an embodiment of the heat dissipation structure, 40, of the present invention. A power tool, 42, has a housing, 30, Which contains a battery pack, 38, which contains internal batteries, 36 that form the heat source, 20. In an embodiment herein, the heat dissipation structure herein contains the PCBA described herein.

The power tool useful herein may be any battery-operated tool such as, but not limited to a drill, a vacuum, a blower, a lawn mower, a hedge trimmer, a saw, a hammer-drill, an edge trimmer, a line trimmer, a sander, a nail gun, a staple gun, a router, an etcher, and a combination thereof; or a drill, a sander, a vacuum, a blower, a lawn mower, an edge trimmer, a line trimmer, and a combination thereof.

The housing, 30, contains an exit vent, 32; or a plurality of exit vents, formed by slits, 34, in the housing. The housing, 30, also contains one or more entrance vents, 44, that is also formed by slits, 34, in the housing. The housing is for a power tool and is well-known in the art.

Such a housing is typically formed of a plastic, a resin, rubber, and a combination thereof. The entrance vent, 44, is at the upstream end of the airflow path formed by arrows B, C, D, and E, whereas the exit vent, 32, is at the downstream end of the airflow path formed by arrows B, C, D, and E. Thus, in an embodiment herein, the fan is downstream of the heat source and the fan therefore does not blow air directly onto the heat source. It is noted that the term “slits” as used herein may indicate any shape which allows air to pass through, and is not intended to be limited to a long, rectangular hole. Thus, the slits may be circular, rectangular, square, etc. as desired.

A fan, 46, is connected to a motor, 48. The fan, 46, moves air towards the exit vent, 32, and creates a low pressure zone which draws air along the airflow path. This in turn transfers heat form the heat source, 20, to the air outside of the power tool, 42. The fan useful herein may be a separate part which is then purposely built into or on to the motor, or may be integral to the motor. When this type of motor turns the spindle, it concurrently generates an air current which can be directed towards the exit vent. In an embodiment herein, when the motor is activated, the fan is activated. Without intending to be limited by theory, it is believed that such an arrangement is especially advantageous, as it generates airflow when the heat source is likely to generate heat—i.e., when the power tool motor is being used to work on something. In addition, it is believed that since the fan is integral with the motor, then little, or no incremental electricity is needed to produce the airflow.

In FIG. 3, the fan, 46, does not blow air directly onto the heat source, 20, but instead is at the distal end of the airflow path. Thus, in an embodiment herein, the fan is distal from the heat source. In an embodiment herein, the fan creates low pressure zone in the airflow path. This low pressure zone then draws air past the heat source so as to cool it down.

In an embodiment herein, the power tool contains a handle, 50, which is typically formed from the housing, 30. The handle has a hollow handle interior, 52, which at least partly contains the airflow path. In FIG. 3, it can be seen that arrow D, which is part of the airflow path, flows through the hollow handle interior, 52.

As noted, the airflow path is shown by arrows B, C, D, and E. Air enters the housing, 30, via the entrance vent's, 44, slits, 34, as shown by arrow B. The battery pack, 38, further contains slits, 34′, that allow air to flow through the battery pack, 38, as shown by arrow C.

FIG. 4 shows a cut-away schematic view of an embodiment of the heat dissipation structure, 40, of the present invention. In this embodiment, which is similar to FIG. 3, the battery pack, 38, is attached directly to the handle, 50, of the power tool, 42, The battery pack, 38, contains a heat source, 20, and is removable, and also contains an entrance vent, 44, formed by slits, 34′, in the bottom of the battery pack, 38. The top of the battery pack, 38, also contains slits, 34′, which lead to the hollow handle interior, 52. The airflow path is similar to that shown in FIG. 3, in that the air enters the bottom of the battery pack, 38, as shown by arrow B, flows through the battery pack, 38, and then into the hollow handle interior, 52, of the power tool, 42, as shown by arrow C. Such an arrangement will help dissipate heat generated by a heat source such as a battery (See FIG. 3 at 36) or a PCBA (see FIG. 1 at 10) in the battery pack, 38.

In an embodiment herein, the power tool contains the PCBA described herein. In an embodiment herein, a battery and/or a battery pack contains the PCBA described herein.

It should be understood that the above only illustrates and describes examples whereby the present invention may be carried out, and that modifications and/or alterations may be made thereto without departing from the spirit of the invention.

It should also be understood that certain features of the invention, which are, for clarity, described in the context of separate embodiments, may also be provided in combination in a single embodiment. Conversely, various features of the invention which are, for brevity, described in the context of a single embodiment, may also be provided for separately or in any suitable subcombination.

1. A printed circuit board assembly (PCBA) comprising:
a heat source which generates heat;
a heat sink connected to the heat source; and
an exit vent positioned adjacent to the heat sink, wherein the heat sink conducts heat from the heat source, wherein the heat sink heats up air surrounding the heat sink to form heated air, and wherein the heated air passes through the exit vent.

2. The PCBA according to claim 1, further comprising:
a heat sink holder connected to the heat sink, wherein the heat sink holder affixes the heat sink to the heat source.

3. The PCBA according to claim 2, wherein the heat sink holder is formed from plastic.

4. The PCBA according to claim 1, further comprising:
a substrate opposite the exit vent.

5. The PCBA according to claim 4, wherein the heat sink is affixed to the substrate.

6. The PCBA according to claim 4, wherein the heat sink holder is affixed to the substrate.

7. The PCBA according to claim 1 wherein the heat sink is formed from a metal.

8. The PCBA according to claim 7, wherein the metal is selected form the group consisting of copper, iron, aluminium, tin, brass, and a combination thereof.

9. The PCBA according to claim 1 further comprising a housing, wherein the housing is distal from the heat source, and wherein the exit vent is located in the housing.

10. A heat dissipation structure comprising:
a fan to move air;
a heat source distal from the fan;
an exit vent proximal to the fan; and
an airflow path running from the heat source to the fan to the exit vent, wherein the heat source heats the air to form heated air, and wherein when the fan is activated, the fan draws air through the airflow path from the heat source and out of the exit vent.

11. The heat dissipation structure according to claim 10, further comprising a printed circuit board assembly (PCBA) including a heat sink connected to the heat source, wherein the heat sink conducts heat from the heat source, wherein the heat sink heats up air surrounding the heat sink to form heated air, and wherein the heated air passes through the exit vent.

12. The heat dissipation structure according to claim 10, further comprising an entrance vent, wherein the airflow path runs from the entrance vent to the heat source to the fan to the exit vent.

13. The heat dissipation structure according to claim 10, wherein the fan is downstream of the heat source, and wherein the fan does not blow air onto the heat source.

14. The heat dissipation structure according to claim 10, wherein the fan creates a low pressure zone in the airflow path and wherein the low pressure zone draws air past the heat source.

15. A power tool comprising:
a handle comprising a hollow handle interior, and
a heat dissipation structure including
a fan to move air;
a heat source distal from the fan;
an exit vent proximal to the fan; and
an airflow path running from the heat source to the fan to the exit vent,
wherein the heat source heats the air to form heated air, and wherein when the fan is activated, the fan draws air through the airflow path from the heat source and out of the exit vent,
wherein the hollow handle interior at least partly contains the airflow path.

16. The power tool according to claim 15, wherein the power tool comprises a motor, and wherein the motor includes the fan.

17. The power tool according to claim 16, wherein when the motor is activated, the fan is activated.

18. The power tool of claim 15 further comprising a printed circuit board assembly (PCBA) including a heat sink connected to the heat source, wherein the heat sink conducts heat from the heat source, wherein the heat sink heats up air surrounding the heat sink to form heated air, and wherein the heated air passes through the exit vent.

19. The power tool of claim 15 further comprising a battery pack including a printed circuit board assembly (PCBA) including a heat sink connected to the heat source, wherein the heat sink conducts heat from the heat source, wherein the heat sink heats up air surrounding the heat sink to form heated air, and wherein the heated air passes through the exit vent.

20. The power tool of claim 15 wherein the heat source is selected from the group consisting of a battery, a motor, a transistor, a gear box, and a combination thereof.
